(19) United States
(12) Patent Application Publication
(10) Pub. No.: US 2007/0020879 A1
(43) Pub. Date: Jan. 25, 2007

(54) Method of forming an isolation layer and method of manufacturing a field effect transistor using the same

(75) Inventors: Eun-Kyung Baek, Suwon-si (KR); Ju-Seon Goo, Suwon-si (KR); Mun-Jun Kim, Suwon-si (KR); Hong-Gun Kim, Suwon-si (KR); Kyu-Tae Na, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd

(21) Appl. No.: 11/484,574

(22) Filed: Jul. 12, 2006

(30) Foreign Application Priority Data
Jul. 19, 2005 (KR) 2005-0065106

(51) Int. Cl. H01L 21/8234; H01L 21/76; H01L 21/336

(52) U.S. Cl. 438/424; 438/435; 438/197

(57) ABSTRACT

In a method of forming a device isolation layer, a trench is formed in a substrate and a preliminary fin is formed on the substrate using a hard mask pattern on a surface of the substrate as an etching mask. A first thin layer is formed on the bottom and sides of the trench. A lower insulation pattern is formed in a lower portion of the trench on the first thin layer, and an upper insulation pattern is formed on the lower insulation pattern. The upper insulation pattern is etched away so that the first thin layer remains on a side surface of the preliminary fin. A device isolation layer is formed in the lower portion of the trench and a silicon fin is formed having a top surface thereof that is higher relative to a top surface of the device isolation layer.

### PRIORITY STATEMENT

This application claims priority under 35 U.S.C. §119 of Korean Patent Application No. 2005-65106, filed on Jul. 19, 2005 in the Korean Intellectual Property Office (KIPO), the entire contents of which are hereby incorporated by reference herein.

### BACKGROUND OF THE INVENTION

1. Field of the Invention

Example embodiments of the present invention in general are related to a method of forming a device isolation layer and to a method of manufacturing a field effect transistor using the same.

2. Description of the Related Art

As semiconductor devices become highly integrated in accordance with the recent technical trend of devices exhibiting high performance, high operation speed and low power consumption at an economical cost, active regions, in which various conductive structures are positioned, have become reduced in size and channel length in devices such as a MOS transistor. The active region has been also shortened. The shortened channel length causes problems including one or more of a punch-through effect, a short channel effect, an increase in parasitic capacitance between a junction area and substrate and a current leakage in the MOS transistor. Accordingly, recent research and development efforts have been focused on reducing the size of a conductive structure in a semiconductor device without adversely reducing performance. A vertical transistor such as a fin structure, a fully depleted lean-channel structure (hereinafter, referred to as DELTA structure) and a gate-all-around structure (hereinafter, referred to as GAA structure) are examples of transistors having a reduced size without decreasing performance thereof

In a fin structured field effect transistor (hereinafter, referred to as fin FET), a gate electrode of the transistor is formed on both sidewalls of the channel fin (both side surfaces of the fin are used as a channel). The gate is under control at both sidewalls thereof, thereby reducing the short channel effect.

Generally, the fin FET is manufactured as follows. A hard mask pattern is formed on a substrate, and the substrate is partially etched away using the hard mask pattern as an etching mask, thereby forming a trench on the substrate. A silicon fin is defined by the trench on the substrate. An isolation layer is formed on the substrate to a thickness that fills up the trench, so as to electrically isolate neighboring fin structures from each other. A top portion of the isolation layer is then etched away so that a top surface of the isolation layer is lower than a top surface of the silicon fin, thereby forming a device isolation layer of which top surface is lower than a top surface of the silicon fin. A gate oxide layer is formed on both side surfaces of the silicon fin, and a gate electrode is formed on the gate oxide layer.

In the above-described conventional fabrication process a fin FET (having a design rule of no more than 60nm), the device isolation layer comprises silicon-on-glass (SOG) because a width of the trench is substantially narrow. However, the device isolation layer comprising SOG is characterized as porous. Thus, the device isolation layer is usually over-etched when a residual oxide on the both side surfaces of the fin and the hard mask pattern are removed by an etching process. As a result, the device isolation layer made of SOG has an undesirable plurality of recesses formed therein due to the over-etch process.

### SUMMARY OF THE INVENTION

An example embodiment of the present invention is directed to a method of forming a device isolation layer. In the method, a hard mask pattern is formed with an opening on a substrate so as to expose a portion of the substrate. The substrate is partially etched using the hard mask pattern as an etching mask to form a trench and a preliminary fin on the substrate. A first thin layer is formed on side and bottom surfaces of the trench. A lower in insulation pattern is formed in a lower portion of the trench on the first thin layer. An upper insulation pattern is formed in an upper portion of the trench including the first thin layer. The upper insulation pattern is partially removed so that a top surface of the upper insulation pattern is lower relative to a top surface of the hard mask pattern, exposing a side surface of the hard mask pattern. A spacer is formed on the side surface of the hard mask pattern. The upper insulation pattern is removed by an etching process using the hard mask pattern and spacer as an etching mask so that the first thin layer remains on a side surface of the preliminary fin. The hard mask pattern, spacer and first thin layer are removed from the preliminary fin by a wet etching process, forming a device isolation layer in the lower portion of the trench and a silicon fin having a top surface thereof is that higher relative to the top surface of the device isolation layer.

### BRIEF DESCRIPTION OF THE DRAWINGS

Example embodiments of the present invention will become more fully understood from the detailed description given herein below and the accompanying drawings, where like elements are represented by like numerals, which are given by way of illustration only and thus are not limitative of the example embodiments herein. FIGS. 1 to 10 are cross sectional views illustrating functions in a method of forming a device isolation layer for a fin FET according to an example embodiment of the present invention.

FIGS. 11 to 13 are perspective views illustrating functions in a method of manufacturing a fin FET including the device isolation layer shown in FIG. 10.

### DETAILED DESCRIPTION OF THE EXAMPLE EMBODIMENTS

The invention is described more fully hereinafter with reference to the accompanying drawings, in which example embodiments of the invention are shown. This invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the size and relative sizes of layers and regions may be exaggerated for clarity.

As used herein, when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, no intervening elements or layers are present. Like numbers refer to like elements throughout. As used herein, the term “and/or” includes any and all combinations of one or more of the associated listed items.

Although the terms first, second, third etc., may be used herein to describe various elements, components, regions, layers and/or sections, these elements, components, regions, layers and/or sections should not be limited by these terms. These terms are used merely to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper”, etc. may be used herein for ease of description to describe one element or feature's relationship to another element(s) or feature(s) as illustrated in the figures. These spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments and is not intended to be limiting of the invention. As used herein, the singular forms “a”, “an” and “the” are intended to include the plural forms as well, unless the context clearly indicates otherwise. The terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and shapes of these regions are not intended to illustrate the actual shape of a region of a device and are not intended to limit the scope of the invention.

Unless otherwise defined, terms (including technical and scientific terms) used herein have the same meaning as commonly understood by one of ordinary skill in the art to which this invention belongs. Moreover, terms such as those defined in commonly used dictionaries should be interpreted as having a meaning that is consistent with the term's meaning in the context of the relevant art and will not be interpreted in an idealized or overly formal sense unless expressly so defined herein.

Method of Forming a Device Isolation Layer for a Fin FET

FIGS. 1 to 10 are cross sectional views illustrating functions in a method of forming a device isolation layer for a FET such as a fin FET, according to an example embodiment of the present invention.

Referring to FIG. 1, a pad oxide layer 102 is formed on a substrate 100 and a hard mask pattern 104 is formed on the pad oxide layer 102, so that the pad oxide layer 102 is partially exposed through the hard mask pattern 104.

In an example, the pad oxide layer 102 may be is formed on a surface of the substrate 100, such as a silicon wafer or other silicon-based structure, to a thickness between about 50 Å to 200 Å using any of a thermal oxidation process, a chemical vapor deposition (CVD) process or other known or equivalent wafer-forming processes. In the present example embodiment, the pad oxide layer 102 is formed to a thickness of about 100 Å.

The hard mask pattern 104, which defines a trench 106 on the substrate 100, is formed on the pad oxide layer 102. A nitride layer (not shown) is formed on the pad oxide layer 102 and a photoresist pattern (not shown) is formed on the nitride layer. A portion of the nitride layer is etched away using the photoresist pattern as an etching mask, thereby forming the hard mask pattern 104 on the pad oxide layer 102.

In an example, the nitride layer may include silicon nitride and may be formed by one of a low pressure chemical vapor deposition (LPCVD) process, a plasma enhanced CVD (PECVD) process using source gases of dichlorosilane gas (SiH2Cl2), silane gas (SiH4) and ammonia (NH3) gas for example, or other known or equivalent large-forming processes.

A photoresist composition may uniformly coat the nitride layer and a baking process may be performed on the coated photoresist composition to form a photoresist layer (not shown) on the nitride layer. A portion of the photoresist layer may be removed by a knowing photoresist process to form a photoresist pattern. The nitride layer is partially exposed through the photoresist pattern.

The exposed nitride layer may be etched away using the photoresist pattern as an etching mask. This forms the hard mask pattern 104 through which a portion of the pad oxide layer 102 is exposed. The photoresist pattern maybe removed from the hard mask pattern 104 by an ashing process, strip process, etc.

Refening to FIG. 2, a portion of the substrate 100 may be partially etched away using the hard mask pattern 104 as an etching mask to form a trench 106 in the substrate 100 and a preliminary fin 110 on the substrate 100. As will be described in more detail below, a channel region of a fin type transistor may be formed on the preliminary fin 110 in a subsequent process.

The pad oxide layer 102 and substrate 100 underlying the pad oxide layer 102 are sequentially etched away using the hard mask pattern 104 as an etching mask, so as to form a trench 106 into the substrate 100. In an example, the trench 106 may be formed to a depth of between about 1500 Å to 3500 Å. In the present example embodiment, the trench 106 is formed to a depth of about 2500 Å.

The etching process for forming trench 106 defines an active region corresponding to the preliminary fin 110, and defines a field region in which a device isolation layer is to be formed on the substrate 100. The substrate 100 includes a cell area having a substantial number of trenches 106 formed thereon and includes a peripheral area having a number of trenches 106 formed thereon. In an example, a width of the trench 106 may be wider or substantially wider in the peripheral area than in the cell area, as shown in FIG. 2.

As shown in FIG. 2, a first thin layer 112 is formed on side and bottom surfaces of the trench 106. The first thin layer 112 may be provided to cure or fix surface damage caused in the etching process for forming the trench 106, and to prevent current leakage from the side and bottom surfaces of the trench 106. In an example, the first thin layer 112 may be an oxide or nitride. In an example, the first thin layer may comprise boron silicate glass (BSG) including about 1% to 4% of boron (B). As an oxide, the first thin layer 112 may be formed using a heat treatment on the side and bottom surfaces of the trench 106. As a nitride, the first thin layer 112 may be formed by using a nitrification treatment on the side and bottom surfaces of the trench 106, or by using a deposition process, such as a low pressure CVD (LPCVD) process, on the side and bottom surfaces of the trench 106. These are merely example oxide/nitride layer forming processes, other layer-forming processes may be evident to one of ordinary skill in the art.

Referring to FIG. 3, a first insulation layer 114 is formed on the substrate 100. In an example, the first insulation layer 114 may be of a thickness which fills up the trench 106, and may have a planarized top surface, for example.

A first preliminary insulation layer (not shown) is formed on the substrate 100 and the mask pattern 104 to a thickness that fills up the trench 106 and covers the first thin layer 112, also covering the mask pattern 104. In the present example embodiment, the first preliminary insulation layer may include a silicon oxide layer formed by a plasma enhanced CVD (PECVD) process. The density of a first preliminary insulation layer composed of silicon oxide is substantially higher than the density of a SOG oxide layer and/or the density of a teethyloxysilane (TEOS) oxide layer. Thus, the first preliminary insulation layer has an etching selectivity with respect to the SOG oxide layer or the TEOS oxide layer in a subsequent plasma enhanced etching process.

Silicon oxide may be deposited onto the substrate 100 and trench 106 by a PECVD process using a processing pressure between about 1 mTorr to 2 mTorr, and a bias power of between about 1,000 W to 1,500 W. These conditions help to ensure that the first preliminary insulation layer is formed on the bottom surface of the trench 106 to a thickness that fills up the trench 106 and covers the hard mask pattern 104. A preliminary void may be formed in the preliminary insulation layer within the trench 106, for example. One of oxygen (O2) gas, helium (He) gas and silane (SiH4) gas may be used as a source gas in the PECVD process.

The first preliminary insulation layer is removed and planarized, such as by a chemical mechanical polishing (CMP) process, until a top surface of the hard mask pattern 104 is exposed, thereby forming the first insulation layer 114 with a planarized top surface, as shown in FIG. 3. The first insulation layer 114 may include a silicon oxide layer formed by a high density plasma CVD (HDP-CVD) process, for example. Referring to FIG. 4, the first insulation layer 114 is partially etched away using the hard mask pattern 104 as an etching mask to form a first insulation pattern 116 filling up a lower portion of the trench 106. An etch-back process is performed on the first insulation layer 114 using the hard mask pattern 104 as an etching mask to remove an upper portion of the first insulation layer 114 at each trench 106. Thus, a portion of the first insulation layer 114 is separated by a trench 106, as shown in FIG. 4. The height of the first insulation layer 114 is lower relative to the preliminary fin 110, such that a top surface of the first insulation layer 114 is lower relative to the top surface of the preliminary fin 110. This height mismatch exposes a side surface of the hard mask pattern 104 and a portion of the side surface of the trench 106 after the first insulation pattern 116 is formed.

Accordingly, the first insulation pattern 116 is configured so that a top surface thereof is lower than the top surface of the preliminary fin 110. The first insulation pattern 116 may be composed of an oxide deposited by a high density plasma CVD (HDP-CVD) process. As to be described later in a subsequent process, the first insulation pattern 116 may be referred to as a lower insulation pattern.

As the first insulation pattern 116 is an HDP oxide, it is substantially less porous than an SOG oxide layer or an undoped silicate glass (USG) oxide layer. Thus, the first insulation pattern 116 is not over-etched in a subsequent cleaning process using a phosphoric solution. That is, little or no recesses are formed in the first insulation pattern 116.

Referring to FIG. 5, a second thin layer 118 composed of an oxide may be uniformly formed on upper side surfaces of the trench 106, on the top surface of the first insulation pattern 116, and on top and side surfaces of the hard mask pattern 104. In an example, the second thin layer 118 may have an etching rate different than the etching rate of the first insulation pattern 116. The second thin layer 118 may be formed to a thickness of between about 50 Å to 100 Å by a CVD process. The second thin layer 118 prevents damage to the side surface of the preliminary fin 110 and the first thin layer 112 in a subsequent dry etching process for forming the device isolation layer.

As an example, the second thin layer 118 may be made of a boron silicate glass (BSG). The BSG may include between about 1% to 4% of boron (B). If the second thin layer 118 includes BGS with a boron (B) content at less than about 1%, the etching rate of the second thin layer 118 may be negligible in a subsequent cleaning process using a phosphorus solution for removing the hard mask pattern 104 and a first thin layer 112 that is formed of a nitride. Using less than 1% boron (B) lengthens the phosphorus cleaning process.

A second preliminary insulation layer 120 is formed on the second thin layer 118 to a thickness that fills up an upper portion of the trench 106 and covers the hard mask pattern 104. In an example, the second preliminary insulation layer 120 may be formed by any of a CVD process, a physical vapor deposition (PVD) process and a spin coating process. The second preliminary insulation layer 120 may be composed of any of a TEOS oxide, USG oxide or a SOG oxide, each of which has a substantially lower porosity than the porosity of the HDP oxide. That is, a TEOS oxide layer, an USG oxide layer or an SOG oxide layer may be used as the second preliminary insulation layer 120. As an example, the TEOS oxide layer is used as the second preliminary insulation layer 120 because of its attractive fill-up characteristics.

Referring to FIG. 6, a second insulation layer 122 is formed on the first insulation pattern 116 in each trench 106. The second preliminary insulation layer 120 and second thin layer 118 rnay then be removed and planarized by a CMP process until the top surface of the hard mask pattern 104 is exposed, as shown in FIG. 6, so that the second preliminary insulation layer 120 and second thin layer 118 remain only in the upper portion of the trench 106, with a space provided adjacent the hard mask pattern 104. In other words, the second thin layer 118 remains on the upper side surfaces of the trench 106 on the top surface of the first insulation pattern 116, and on the side surfaces of the hard mask pattern 104. The second preliminary insulation layer 120 fills the upper portion of the trench 106 and the space adjacent the hard mask pattern 104. Accordingly, the second preliminary insulation layer 120 is formed into the second insulation layer 122 on top of the first insulation pattern 116 and may be referred to as an upper insulation layer in the present example embodiment.

Referring to FIG. 7, a portion of the second insulation layer 122 is etched away, i.e., partially etched using the hard mask pattern 104 as an etching mask. This forms a second insulation pattern 124 that fills up the upper portion of the trench 106. The second insulation pattern 124 may be an oxide such as one of a TEOS oxide, a USG oxide and a SOG oxide, for example.

An etch-back process is performed on the second insulation pattern 124 using the hard mask pattern 104 as an etching mask so that an upper portion of the second insulation pattern 124 is removed at each trench 106, and so that the second insulation pattern 124 remains only in the upper portion of the trench 106. The height of the second insulation pattern 124 is reduced. As can be seen in FIG. 7, a top surface of the second insulation pattern 124 is lower relative to the top surface of the hard mask pattern 104, so that a side surface of the hard mask pattern 104 is exposed after forming the second insulation pattern 124. In the present example embodiment, the second insulation pattern 124 corresponds to an upper insulation pattern. The second thin layer 118 on side surfaces of the hard mask pattern 104 is also removed from the hard mask pattern 104.

Referring to FIG. 8, a mask spacer 130 may be formed on a side surface of the hard mask pattern 104. A spacer nitride layer (not shown) may be formed on side and top surfaces of the hard mask pattern 104 and on a top surface of the second insulation pattern 124 to a given uniform thickness. The thickness of the spacer nitride layer may be greater than or equal to the thickness of the second thin layer 118, so that the second thin layer 118 at the side surface of the preliminary fin 110 is covered with the spacer nitride layer.

Then, an etch-back process, i.e.,(dry etching process) is performed on the spacer nitride layer, to form a mask spacer 130 on the side surface of the hard mask pattern 104. The mask spacer 130 prevents the second thin layer 118 adjacent to the side surface of the preliminary fin 110 from being removed from the substrate 100 in a subsequent dry etching process for forming the device isolation layer (not shown). Referring to FIG. 9, the second insulation pattern 124 is etched away using the hard mask pattern 104 and mask spacer 130 as an etching mask, so that the second thin layer 118 remains only on the side surface of the preliminary fin 110. As an example, the second insulation pattern 124 may be removed from the substrate 100 by a plasma enhanced etching process using the hard mask pattern 104 and mask spacer 130 as an etching mask. The second insulation pattern 124 is substantially more porous than the first insulation pattern 116. As such, a plasma enhanced etching process may more easily remove the second insulation pattern 124 from the substrate 100.

In the above plasma enhanced etching process for removing the second insulation pattern 124, the second thin layer 118 adjacent to the side surface of the preliminary fin 110 is covered with the mask spacer 130. The second thin layer 118 remains on the top surface of the first insulation pattern 116 and on the first thin layer 112 adjacent to the side surface of the preliminary fin 110. The second thin layer 118 prevents damage to the first thin layer 112 in the plasma enhanced etching process, and also prevents the first insulation pattern 116 from being etched away by the plasma enhanced etching process.

The second insulation pattern 124 is described as being removed from the substrate 100 using a plasma enhanced etching process. Additionally, the second thin layer 118 on the top surface of the first insulation pattern 116 may also be removed using the plasma enhanced etching process, as would be evident to one of ordinary skill in the art.

Referring to FIG. 10, the hard mask pattern 104 and mask spacer 130 are removed from the substrate 100, and the second thin layer 118 (on the first thin layer 112 adjacent to the upper surface of the preliminary fin 110) is removed from the first thin layer 112. The first thin layer 112 on the upper surface of the trench 106 is also removed so that only the first thin layer 112 and first insulation pattern 116 remain in the lower portion of the trench 106. This forms a device isolation layer 140 and a silicon fin 111. The silicon fin 111 has a top surface higher relative to the top surface of device isolation layer 140, as shown in FIG. 10.

In an example, the hard mask pattern 104, mask spacer 130 and first thin layer 112 of nitride are removed from the substrate 100 with a wet cleaning process that uses a phosphorus solution. The second thin layer 118 of oxide (adjacent to the side surface of the preliminary fin 110) is also removed from the substrate 100 by the same phosphorus solution. Accordingly, the second thin layer 118 is removed from the substrate 100 simultaneously with the hard mask pattern 104, mask spacer 130 and first thin layer 112 comprising nitride in the wet cleaning process.

In contrast, the first insulation pattern 116 of the device isolation layer 140 has a superior etching resistance against the phosphoric solution, so as to prevent over-etching the first insulation pattern 116 during the above phosphorus cleaning process. As a result, the first insulation pattern 116 has little or no recesses therein.

The device isolation layer 140 includes the first insulation pattern 116, and the portion of the first thin layer 112 that remains on the side surfaces of the lower portion of the trench 106. A top surface of the device isolation layer 140 is lower relative to the top surface of the silicon fin 111 , on which a channel region for a fin FET may be formed, for example. Accordingly, the silicon fin 111 may protrude from the substrate 100 and a lower portion of the silicon fin 111 may be enclosed by the device isolation layer 140.

According to the present example embodiment, no recesses (caused by over-etching the device isolation layer 140) are formed on a top surface of the device isolation layer 140, thereby preventing operation failures of a fin FET.

Method of Manufacturing a Fin FET

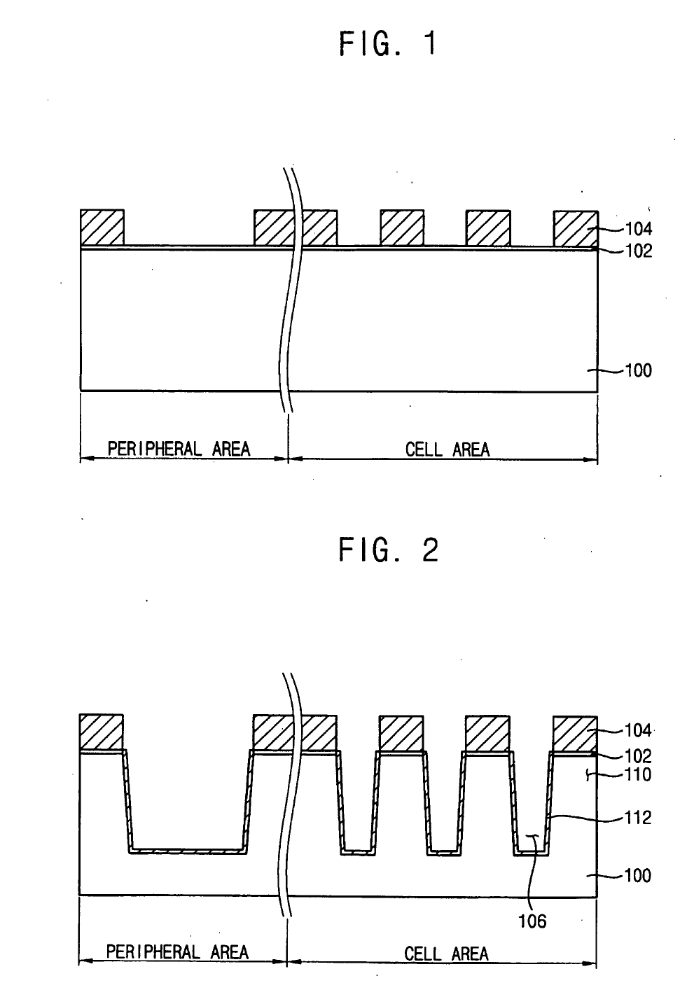

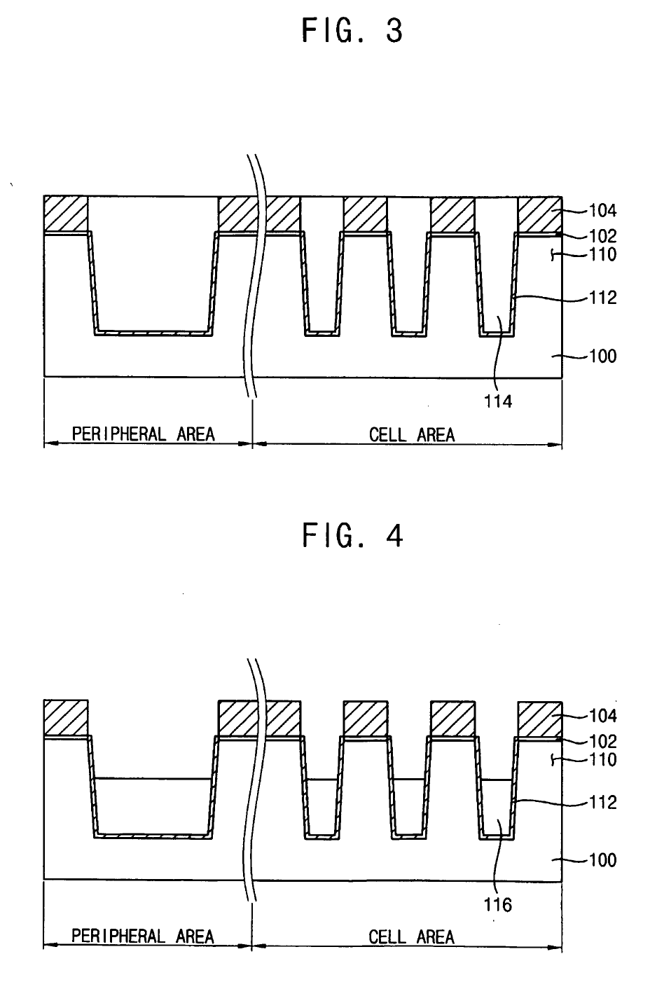

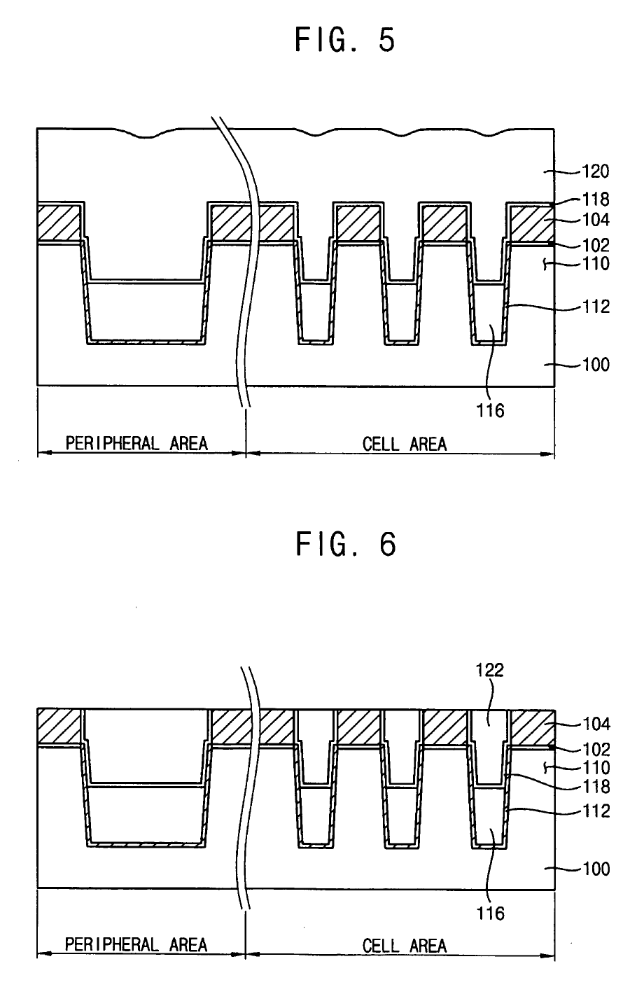

FIGS. 11 to 13 are perspective views illustrating functions in a method of manufacturing a fin FET including the device isolation layer shown in FIG. 10. The device isolation layer 140 and silicon fin 111 of the present example embodiment are the same as described with reference to FIGS. 1 to 10; thus a further detailed description of the device isolation layer 140 and the silicon fin 111 are omitted for purposes of brevity. In FIGS. 11 to 13, the same reference numerals denote the same elements in FIGS. 1 to 10.

Referring to FIG. 1, a gate insulation layer 150 is formed on the substrate 100 silicon fins 111, on side surfaces of trench 106, and on a top surface of first insulation pattern 116 of device isolation layer 140. The top surface of silicon fins 111 are higher relative to the top surface of the device isolation layer 140. In an example, the silicon fins 111 may have a protruding shape extending up from the device isolation layer 140.

The gate insulation layer 150 may be formed on surfaces of the silicon fins 111, which are used as channel regions of the fin FET, by a thermal oxidation process or a CVD process, for example. In FIG. 11, the gate insulation layer 150 may include silicon oxide (SiO₂). As an example, the gate insulation layer 150 may be composed of a metal oxide layer having a dielectric constant greater than silicon oxide, which may be applied using an atomic layer deposition (ALD) process. The ALD process may be described as follows: a source material is provided and a first purging process is performed for removing any residual source material. An oxidizing agent is then provided, and a residual oxidizing agent is removed by a second purging process. Sequentially performing these processes completes a cycle of the ALD process. The number of times the ALD cycle is repeated may determine the thickness of the gate insulation layer 150. For example, the ALD cycle may be repeated at least once so that metal oxide layer is formed on the silicon fin 111 as the gate insulation layer 150.

The source material includes a metal precursor. For example, the source material may include tetrakis ethyl methyl amino hafnium (TEMAH, Hf[NC₂H₅CH₃]₄) or hafnium butyl oxide (Hf(O-tBu)₄) when a hafnium precursor is used in the ALD process, and trimethyl aluminum (TMA, Al(CH₃)₃) when an aluminum precursor is used in the ALD process. Examples of the oxidizing agent may include ozone (O₃), vapor (H₂O), non-activated oxygen (O₂), oxygen (O₂) activated by plasma or remote plasma, etc. These can be used alone or in combinations thereof. For example, when the gate insulation layer 100 includes a hafnium oxide layer, the ALD process includes providing TEMAH removing any residual TEMAH by purging, providing ozone (O₃) gas as an oxidizing agent removing any residual ozone (O₃) gas by another purging process.

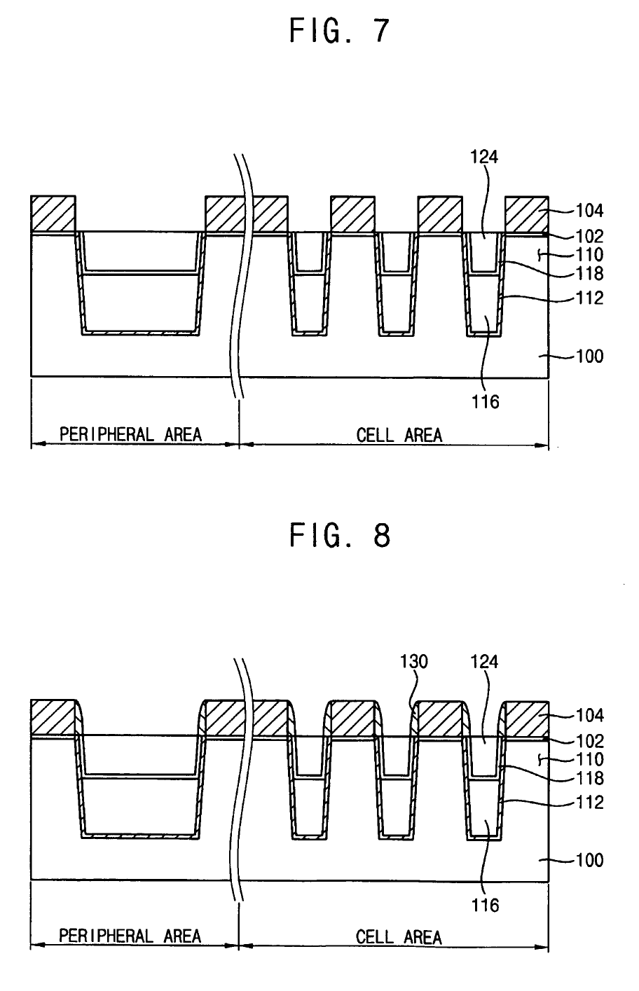

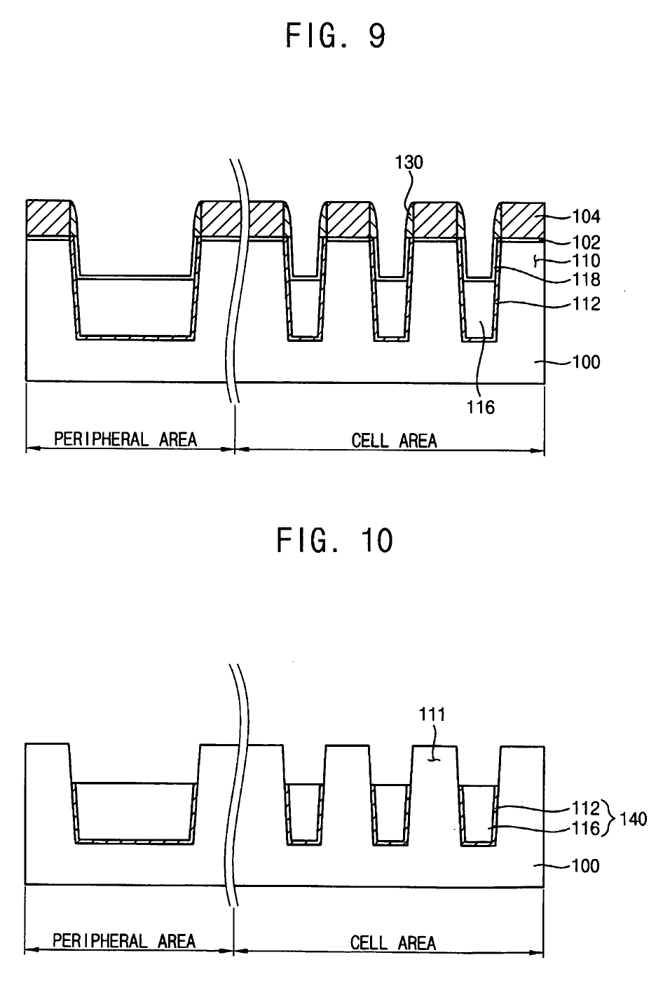

Referring to FIG. 12, a conductive layer 154 and a gate mask pattern (not shown) may be sequentially formed on the gate insulation layer 150 and the device isolation layer 140. The conductive layer 154 may include polysilicon doped with impurities, metal, metal nitride, metal silicide, etc. In an example, the conductive layer 154 may be formed as a multilayer structure including a doped polysilicon layer and a metal silicide layer. The conductive layer 154 is used to be form the gate electrode of the FET fin in a subsequent process. The gate mask pattern has an etching selectivity with respect to an insulation interlayer (not shown) that is to be formed in a subsequent process. For example, if the insulation interlayer includes an oxide such as silicon oxide, the gate mask pattern comprises silicon nitride.

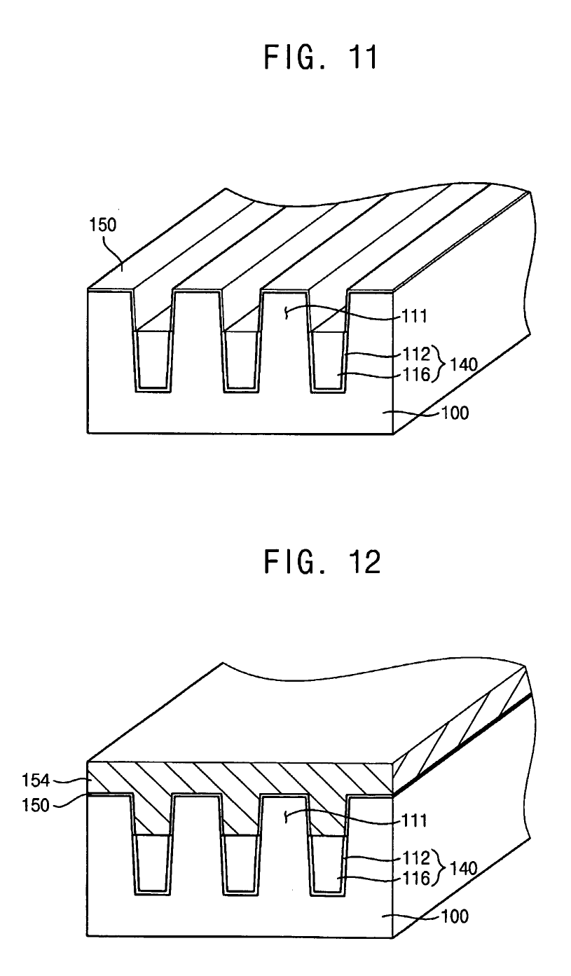

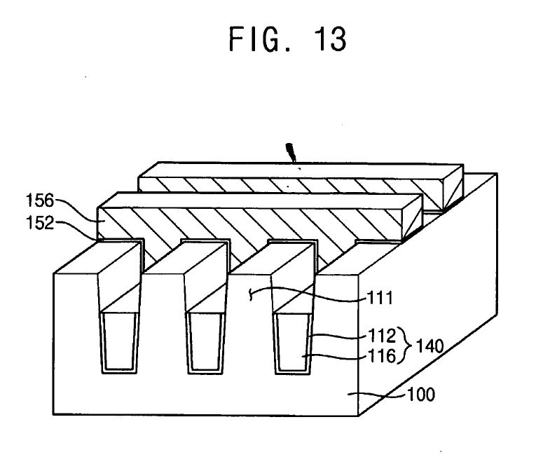

Referring to FIG. 13, the conductive layer 154 and the gate insulation layer 150 may be sequentially removed by an etching process using the gate mask pattern as an etching mask, thereby forming a gate insulation pattern 152 and a gate electrode 156 on the silicon fin 111. Accordingly, a gate structure including the gate insulation pattern 152 and the gate electrode 156 is formed on the silicon fin 111.

Impurities are implanted onto the surface of the silicon fin 111 using the gate structure as an ion-implantation mask. A heat treatment is then performed on the silicon fin 111 to form source/drain regions (not shown) at surface portions of the silicon fin 111 exposed between the gate structures. As a result, the a size of the channel region of the fin FET is enlarged, potentially reducing and/or eliminating short channel effects in the fin FET.

According to an example embodiment of the present invention, a lower insulation pattern 116 of the device isolation layer 140 for a fin FET has an etching rate different from that of an oxide layer that remains on a side surface of the silicon fin 111. Thus, the lower insulation pattern 116 has an etching resistance to an etchant for a wet etching process, in which the oxide layer on the side surface of the silicon fin 111 and the hard mask pattern 104 are removed from the substrate 100. As a result, over-etching the device isolation layer 140 (in the etching process for removing the oxide layer on the side surface of the silicon fin 111 and the hard mask pattern 104) can be avoided. Further, little or no recesses (typically caused by the over-etching) are formed on a top surface of the device isolation layer 140, thereby reducing and/or preventing the likelihood of operation failures of the fin FET.

Although the example embodiments of the present invention have been shown and described, it is understood that the present invention should not be limited to these example embodiments. As such, various changes and modifications can be made by one skilled in the art within the spirit and scope of the example embodiments of the present invention, as is hereinafter claimed.

What is claimed is:

1. A method of forming a device isolation layer, comprising:
forming a hard mask pattern with an opening on a substrate so as to expose a portion of the substrate;
forming a trench and a preliminary fin on the substrate by partially etching the substrate using the hard mask pattern as an etching mask;
forming a first thin layer on side and bottom surfaces of the trench;
forming a lower insulation pattern in a lower portion of the trench on the first thin layer;
forming an upper insulation pattern in an upper portion of the trench including the first thin layer;
partially removing the upper insulation pattern so that a top surface of the upper insulation pattern is lower relative to a top surface of the hard mask pattern, exposing a side surface of the hard mask pattern;
forming a spacer on the side surface of the hard mask pattern;
removing the upper insulation pattern by an etching process using the hard mask pattern and spacer as an etching mask so that a portion of the first thin layer remains on a side surface of the preliminary fin; and
forming a device isolation layer in the lower portion of the trench and a silicon fin having a top surface higher relative to the top surface of the device isolation layer by removing the hard mask pattern, spacer and first thin layer from the preliminary fin with a wet etching process.

2. The method of claim 1, wherein forming the trench and preliminary fin further includes forming a channel region for a fin type transistor along a surface of the preliminary fin.

3. The method of claim 1, wherein the first thin layer is formed to a uniform thickness.

4. The method of claim 1, wherein the first thin layer has an etching selectivity with respect to the lower insulation pattern.

5. The method of claim 1, further comprising forming a second thin layer on bottom and side surfaces of the trench after the preliminary fin is formed on the substrate.

6. The method of claim 1, wherein forming the lower insulation pattern includes:
forming a preliminary lower insulation layer on the substrate at a thickness which fills up the trench and covers the hard mask pattern;
removing the preliminary lower insulation layer with a chemical mechanical polishing (CMP) process until a top surface of the hard mask pattern is exposed, so that the preliminary lower insulation layer remains in the trench is level with the top surface of the hard mark pattern; and
removing an upper portion of the lower insulation layer such that a top surface of the lower insulation layer is lower than a top surface of the preliminary fin, exposing a side surface of the upper portion of the trench.

7. The method of claim 1, wherein the lower insulation pattern includes an oxide layer formed by a high density plasma chemical vapor deposition (HDP CVD) process.

8. The method of claim 1, wherein the first thin layer comprises boron silicate glass (BSG).

9. The method of claim 8, wherein the first thin layer includes about 1% to 4% of boron (B).

10. The method of claim 1, wherein the upper insulation pattern includes an oxide selected from the group consisting of tetraethyloxysilane (TEOS) oxide, undoped silicate glass (USG) oxide and spin-on glass (SOG) oxide.

11. The method of claim 1, wherein partially removing the upper insulation pattern is performed by a dry etching process using high density plasma.

12. The method of claim 1, wherein the first thin layer is removed from the side surface of the preliminary fin simultaneously with the hard mask pattern and spacer.

13. The method of claim 1, wherein the wet etching process for removing the hard mask pattern, spacer and first thin layer is performed using a phosphorus solution as an etchant.

14. A method of manufacturing a fin type field effect transistor, comprising:
forming a device isolation layer for the fin type field effect transistor in accordance with the method of claim 1;
forming a gate insulation layer on a surface of the silicon fin; and
forming a conductive layer on the silicon fin including the gate insulation layer and on the device isolation layer.

15. The method of claim 14, wherein the lower insulation pattern includes an oxide layer formed by a HDPCVD process.

16. The method of claim 14, wherein the first thin layer comprises boron silicate glass (BSG) including about 1% to 4% of boron (B).

17. The method of claim 14, wherein the upper insulation pattern includes an oxide selected from the group consisting of TEOS oxide, USG oxide and SOG oxide.

18. A method of forming a device isolation layer, comprising forming a trench in a substrate and a preliminary fin on the substrate using a hard mask pattern on the surface of the substrate as an etching mask;
forming a first thin layer on side and bottom surfaces of the trench and on a side surface of the preliminary fin;
forming a first insulation pattern in a lower portion of the trench on the first thin layer;
forming a second insulation pattern on the first insulation pattern within the trench so that a top surface of the second insulation pattern is lower relative to the hard mask pattern top surface;
forming a spacer on a side surface of the hard mask pattern;
etching the second insulation pattern using the hard mask layer as an etching mask so that the first thin layer remains on a side surface of the preliminary fin; and
forming a device isolation layer in the lower portion of the trench and a silicon fin having a top surface higher relative to the top surface of the device isolation layer by removing the hard mask pattern, spacer and first thin layer from the preliminary fin.

19. The method of claim 18, wherein forming the trench and preliminary fin further includes forming a channel region for a fin type transistor along a surface of the preliminary fin.

20. The method of claim 18, wherein the first thin layer is formed to a uniform thickness.

21. The method of claim 18, wherein the first thin layer has an etching selectivity with respect to the lower insulation pattern.

22. The method of claim 18, further comprising forming a second thin layer on bottom and side surfaces of the trench after the preliminary fin is formed on the substrate.

23. The method of claim 18, wherein the formed isolation layer has no recesses thereon.

24. A method of manufacturing a fin type field effect transistor, comprising:
forming a device isolation layer for the fin type field effect transistor in accordance with the method of claim 18;
forming a gate insulation layer on a surface of the silicon fin; and
forming a conductive layer on the silicon fin including the gate insulation layer and on the device isolation layer.
